(19) United States
(12) Patent Application Publication
(10) Pub. No.: US 2015/0170996 A1
(43) Pub. Date: Jun. 18, 2015

(54) THROUGH-MESH-PLANE VIAS IN A MULTI-LAYERED PACKAGE

(71) Applicant: International Business Machines Corporation, Armonk, NY (US)

(72) Inventors: Dulce M. Altabella Lazzi, Salt Lake City, UT (US); Wiren D. Becker, Hyde Park, NY (US); Jinwoo Choi, Austin, TX (US); Rohan U. Mandrekar, Austin, TX (US)

(73) Assignee: International Business Machines Corporation, Armonk, NY (US)

(21) Appl. No.: 14/132,287

(22) Filed: Dec. 18, 2013

(51) Int. Cl. H01L 23/48; H01L 21/768

(52) U.S. Cl. CPC H01L 23/481; H01L 21/768

(57) ABSTRACT

In some embodiments, a multi-layered package includes a plurality of mesh planes. The multi-layered package includes at least one through-mesh-plane via positioned to traverse the plurality of mesh planes, wherein the at least one through-mesh-plane via is to intersect the plurality of mesh planes. The multi-layered package includes at least one signal via positioned to traverse the plurality of mesh planes, wherein the at least one signal via is positioned within an opening of the plurality of mesh planes and is positioned adjacent to the at least one through through-mesh-plane via.

### BACKGROUND

Embodiments of the inventive subject matter generally relate to multi-layered packages and, more particularly, to multi-layered packages with through-mesh-plane vias.

Multi-layered packages are typically used for mounting or supporting semiconductor chips. A typical semiconductor chip includes miniaturized semiconductor devices formed on a semiconductor substrate. The semiconductor substrate, such as silicon, is usually brittle, and relies on the carrier, on which it is mounted, for support and mechanical rigidity. In addition, to providing support, the carrier provides mechanical and electrical interfaces between the chip and a device, such as a printed circuit board (PCB) or the like, on which the chip/carrier combination is mounted. The combination is termed a “chip carrier” or “chip package”, which can be a single-chip module (SCM) or a multi-chip module (MCM).

A multi-layered package can be attractive for interfacing SCM or MCM to a Printed Circuit Board (PCB) or the like. However, these packages can provide very high wiring and power densities. The densities are hallmarks of an efficient and high performance system. A conventional multi-layered package is usually formed from a plurality of signal planes carrying electrical conductors, and sandwiched between a plurality of mesh planes. Each signal plane is placed between upper and lower mesh planes, which provide power (Vdd) and ground (gnd) potential to the signal planes. Each mesh plane is, usually, a grid structure, which is formed from intersecting reference lines accessible by vias. The grid structure may be fabricated on a ceramic substrate.

To meet performance requirements, imposed by high performance systems, there has been an increase in the number of signal lines and signal speed provided in a multi-layered package. As the speed and number of signal lines increase, the potential for cross-talk between signal lines in the same layer, and signal lines in adjacent layers, also, increases. The cross-talk results in the creation of electrical noise, which adversely affects the signaling rates and performance in a multi-layered package.

### SUMMARY

In some embodiments, a multi-layered package includes a plurality of mesh planes. The multi-layered package includes at least one through-mesh-plane via positioned to traverse the plurality of mesh planes, wherein the at least one through-mesh-plane via is to intersect the plurality of mesh planes. The multi-layered package includes at least one signal via positioned to traverse the plurality of mesh planes, wherein the at least one signal via is positioned within an opening of the plurality of mesh planes and is positioned adjacent to the at least one through-mesh-plane via.

In some embodiments, a system includes a printed circuit board and a multi-layered package positioned on top of the printed circuit board and communicatively coupled to the printed circuit board. The multi-layered package includes a plurality of mesh planes. The multi-layered package includes at least one through-mesh-plane via positioned to traverse the plurality of mesh planes, wherein the at least one through-mesh-plane via is to intersect the plurality of mesh planes. The multi-layered package includes at least one signal via positioned to traverse the plurality of mesh planes, wherein the at least one signal via is positioned within an opening of the plurality of mesh planes and is positioned adjacent to the at least one through-mesh-plane via. The system includes an integrated circuit device positioned on top of the multi-layered package and communicatively coupled to the at least one signal via.

In some embodiments, a method includes fabricating a multi-layered package. The fabricating includes forming a plurality of mesh planes. The fabricating includes forming at least one through-mesh-plane via positioned to traverse the plurality of mesh planes, wherein the at least one through-mesh-plane via is to intersect the plurality of mesh planes. The fabricating includes forming at least one signal via positioned to traverse the plurality of mesh planes, wherein the at least one signal via is positioned within an opening of the plurality of mesh planes and is positioned adjacent to the at least one through-mesh-plane via.

### BRIEF DESCRIPTION OF THE DRAWINGS

The present embodiments may be better understood, and numerous objects, features, and advantages made apparent to those skilled in the art by referencing the accompanying drawings.

FIG. 1 depicts a system having a multi-layered package that includes through-mesh-plane vias, according to some embodiments.

FIG. 2 depicts a top view of a more detailed diagram of a multi-layered package having through-mesh-plane vias, according to some embodiments.

FIG. 3 depicts a top view of a more detailed diagram of a multi-layered package having through-mesh-plane vias, according to some other embodiments.

FIG. 4 depicts a cross sectional view of a more detailed diagram of a multi-layered package having through-mesh-plane vias, according to some embodiments.

FIG. 5 depicts a cross sectional view of a more detailed diagram of a multi-layered package in which the mesh planes are ground planes, according to some embodiments.

FIG. 6 depicts a cross sectional view of a more detailed diagram of a multi-layered package in which the mesh planes are a combination of ground planes and power planes, according to some embodiments.

FIG. 7 depicts a cross sectional view of a more detailed diagram of a multi-layered package in which the mesh planes are a combination of ground planes and power planes, according to some other embodiments.

FIG. 8 depicts a flowchart of operations for fabrication of a multi-layered package, according to some embodiments.

### DESCRIPTION OF EMBODIMENT(S)

The description that follows includes exemplary systems, methods, techniques, instruction sequences and computer program products that embody techniques of the present inventive subject matter. However, it is understood that the described embodiments may be practiced without these specific details. For instance, although examples refer to a multi-layered package used for coupling an integrated circuit device to a printed circuit board, various embodiments can be used coupling an integrated circuit device to other types of electrical components. In other instances, well-known structures and techniques have not been shown in detail in order not to obfuscate the description.

Various embodiments reduce the noise coupling between signal vias in multi-layered packages. Various embodiments incorporate one more through-mesh-plane vias that are coupled across multiple mesh planes of a mesh plane structure to reduce the noise coupling between signal vias. As further described below, the one or more through-mesh-plane vias are positioned between the signal vias and are coupled to multiple mesh planes. In some embodiments, the multi-layered packages are multi-layered ceramic packages. The multi-layered packages can include a number of mesh planes that form a mesh plane structure. Each of the mesh planes can be a voltage or power plane for supplying power to different components in the multi-layered package or a ground plane to serve as a ground to different components in the multi-layered package. As further described below, various embodiments can be configured to reduce near-end (NE) crosstalk and/or far-end (FE) crosstalk.

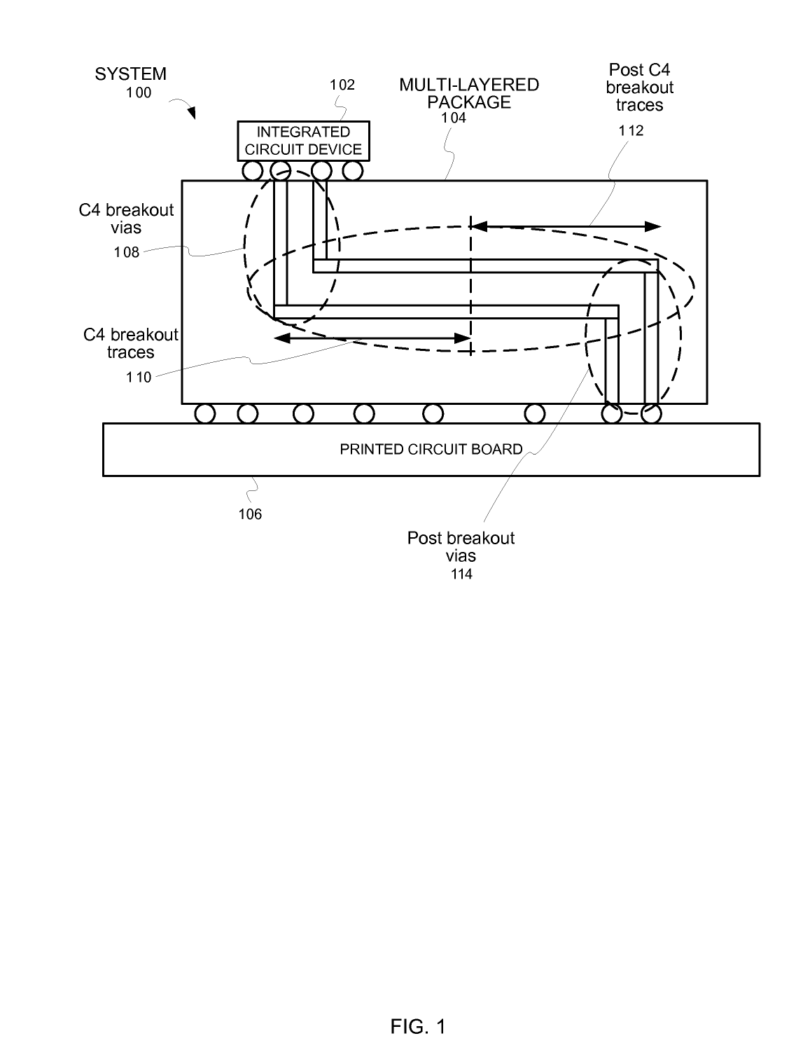

FIG. 1 depicts a system having a multi-layered package that includes through-mesh-plane vias, according to some embodiments. In particular, FIG. 1 depicts a system 100 that includes a multi-layered package 104 for coupling an integrated circuit device 102 to a printed circuit board 106. The multi-layered package 104 can include a number of traces shown as positioned laterally and a number of vias positioned longitudinally. In this example, the multi-layer package 104 includes C4 breakout vias 108 that are coupled between the integrated circuit device 102 and the C4 breakout traces 110. The C4 breakout traces 110 are coupled between the C4 breakout vias 108 and post C4 breakout traces 112. The post breakout vias 114 are coupled between the C4 breakout traces 110 and the printed circuit board 106. The traces and the vias can be used for signal transmission, power transmission, grounds, etc. In this example, the system includes two sets of vias and traces for electrical coupling between the integrated circuit device 102 and the printed circuit board 106. As an example, a first set of vias and traces that are electrically coupled together can be used for signal transmission between the integrated circuit device 102 and the printed circuit board 106. And a second set of vias and traces that are electrically coupled together can be used for power. As further described below, various embodiments include one or more through-mesh-plane vias positioned between the signal vias and coupled to multiple mesh planes for reducing noise coupling between the signal vias in the multi-layered package 104.

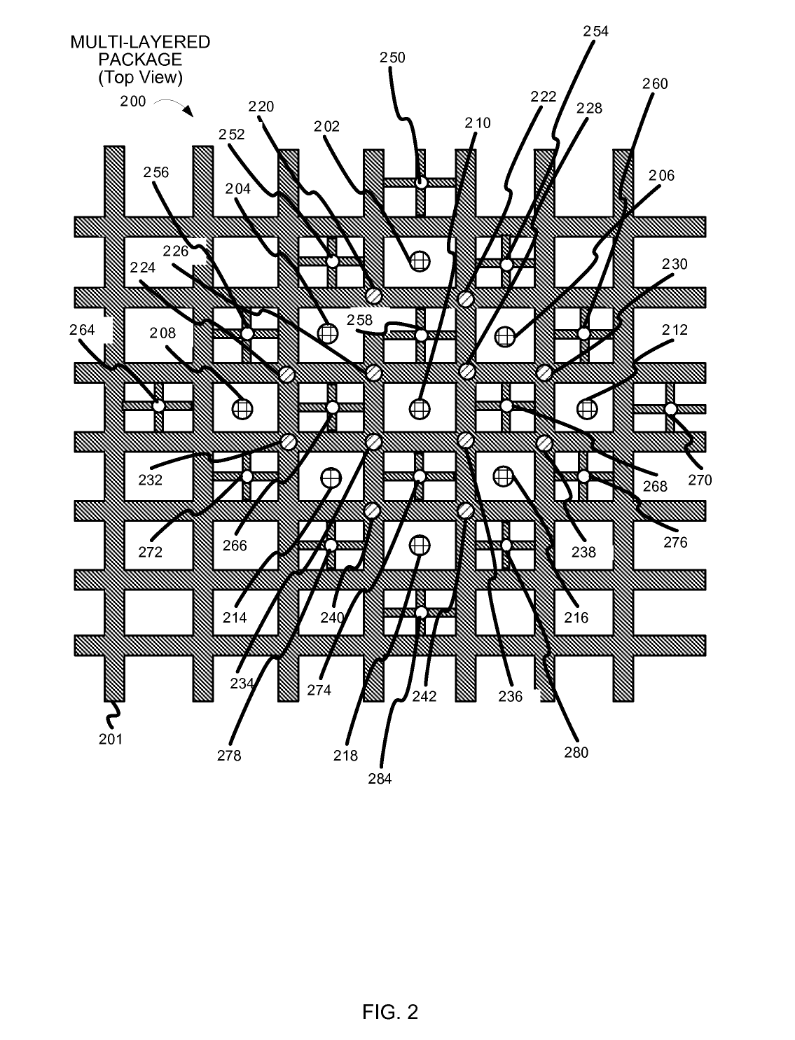

FIG. 2 depicts a top view of a more detailed diagram of a multi-layered package having through-mesh-plane vias, according to some embodiments. In particular, FIG. 2 depicts a top view of a multi-layered package 200 that includes a mesh plane 201. As shown, the mesh plane 201 forms a mesh with a number of horizontal lines and vertical lines that criss-cross. In this example, the mesh plane 201 comprises a ground plane. Alternatively, the mesh plane 201 can be a voltage plane. A number of openings are formed in the mesh plane 201 between the intersections of the horizontal lines and vertical lines. There can be a multiple of these mesh planes formed on top of each other at spaced intervals. Also, there can be signal layers formed between the mesh planes. In signal layers, traces like C4 breakout traces and post C4 breakout traces exist. In this example, there are a number of signal vias (i.e., post-breakout vias) formed within the openings of the mesh plane 201 and these signal vias are connected to post C4 breakout traces. In particular, the multi-layered package 200 includes a signal via 202, a signal via 204, a signal via 206, a signal via 208, a signal via 210, a signal via 212, a signal via 214, a signal via 216, and a signal via 218. With reference to FIG. 1, the signal vias 202-218 can examples of the post breakout vias 114.

The multi-layered package 200 also includes a number of through-mesh-plane vias that are within the mesh plane 201. In this example, the multi-layered package 200 includes 12 through-mesh-plane vias—a through-mesh-plane via 220, a through-mesh-plane via 222, a through-mesh-plane via 224, a through-mesh-plane via 226, a through-mesh-plane via 228, a through-mesh-plane via 230, a through-mesh-plane via 232, a through-mesh-plane via 234, a through-mesh-plane via 236, a through-mesh-plane via 238, a through-mesh-plane via 240, and a through-mesh-plane via 242. In this example, the through-mesh-plane vias are positioned at different intersections of the lines of the mesh plane 201. The through-mesh-plane via 220 and the through-mesh-plane via 222 are along a same horizontal mesh line at two different intersections with two different vertical mesh lines of the mesh plane 201. The through-mesh-plane via 224, the through-mesh-plane via 226, the through-mesh-plane via 228, and the through-mesh-plane via 230 are along a same horizontal mesh line at four different intersections with four different vertical mesh lines of the mesh plane 201. The through-mesh-plane via 232, the through-mesh-plane via 234, the through-mesh-plane via 236, and the through-mesh-plane via 238 are along a same horizontal mesh line at four different intersections with four different vertical mesh lines of the mesh plane 201. The through-mesh-plane via 240 and the through-mesh-plane via 242 are along a same horizontal mesh line at two different intersections with two different vertical mesh lines of the mesh plane 201. As further described below, the through-mesh-plane vias 220-242 extend down to intersect with one or more mesh planes.

In this example, the multi-layered package 200 also includes a number of ground vias. In this example, the multi-layered package 200 includes 16 ground vias—a ground via 250, a ground via 252, a ground via 254, a ground via 256, a ground via 258, a ground via 260, a ground via 262, a ground via 264, a ground via 266, a ground via 268, a ground via 270, a ground via 272, a ground via 274, a ground via 276, a ground via 278, a ground via 280, a ground via 282, and a ground via 284. In this example, a ground via is positioned in a cross within a mesh opening of the mesh plane 201. The ground vias may be positioned in mesh openings where signal vias are not positioned. In this example, the ground via 250 is positioned in a mesh opening that is above the mesh opening where the signal via 202 is positioned. The ground via 252 is positioned in a mesh opening that is left of the mesh opening where the signal via 202 is positioned. The ground via 254 is positioned in a mesh opening that is right of the mesh opening where the signal via 202 is positioned.

The ground via 256 is positioned in a mesh opening that is left of the mesh opening where the signal via 204 is positioned. The ground via 258 is positioned in a mesh opening that is left of the mesh opening where the signal via 206 is positioned. The ground via 260 is positioned in a mesh opening that is right of the mesh opening where the signal via 206 is positioned. The ground via 264 is positioned in a mesh opening that is left of the mesh opening where the signal via 208 is positioned. The ground via 266 is positioned in a mesh opening that is left of the mesh opening where the signal via 210 is positioned. The ground via 268 is positioned in a mesh opening that is left of the mesh opening where the signal via 212 is positioned. The ground via 270 is positioned in a mesh opening that is right of the mesh opening where the signal via 212 is positioned.

The ground via 272 is positioned in a mesh opening that is left of the mesh opening where the signal via 214 is positioned. The ground via 274 is positioned in a mesh opening that is left of the mesh opening where the signal via 216 is positioned. The ground via 276 is positioned in a mesh opening that is right of the mesh opening where the signal via 216 is positioned. The ground via 278 is positioned in a mesh opening that is left of the mesh opening where the signal via 218 is positioned. The ground via 280 is positioned in a mesh opening that is right of the mesh opening where the signal via 218 is positioned. The ground via 284 is positioned in a mesh opening that is below the mesh opening where the signal via 218 is positioned.

As further described below, the ground vias 250-284 extend down to intersect with one or more other mesh planes. In some embodiments, the ground vias 250-284 can extend down to intersect the same number of other mesh planes as the through-mesh-plane vias 220-242. Alternatively, the ground vias 250-284 can extend down to intersect a different number of other mesh planes as the through-mesh-plane vias 220-242.

Because the through-mesh-plane vias 220-242 are positioned adjacent to and between the signal vias 202-218 and because the through-mesh-plane vias 220-242 are within the mesh plane and extend down to intersect other mesh planes in the multi-layered package 200, the noise coupling among the signals in the signal vias 202-218 is reduced. Based on 3-D EM (electromagnetic) modeling, the locations of the through-mesh plane vias 220-242 (at the intersections) minimize far-end (FE) noise coupling.

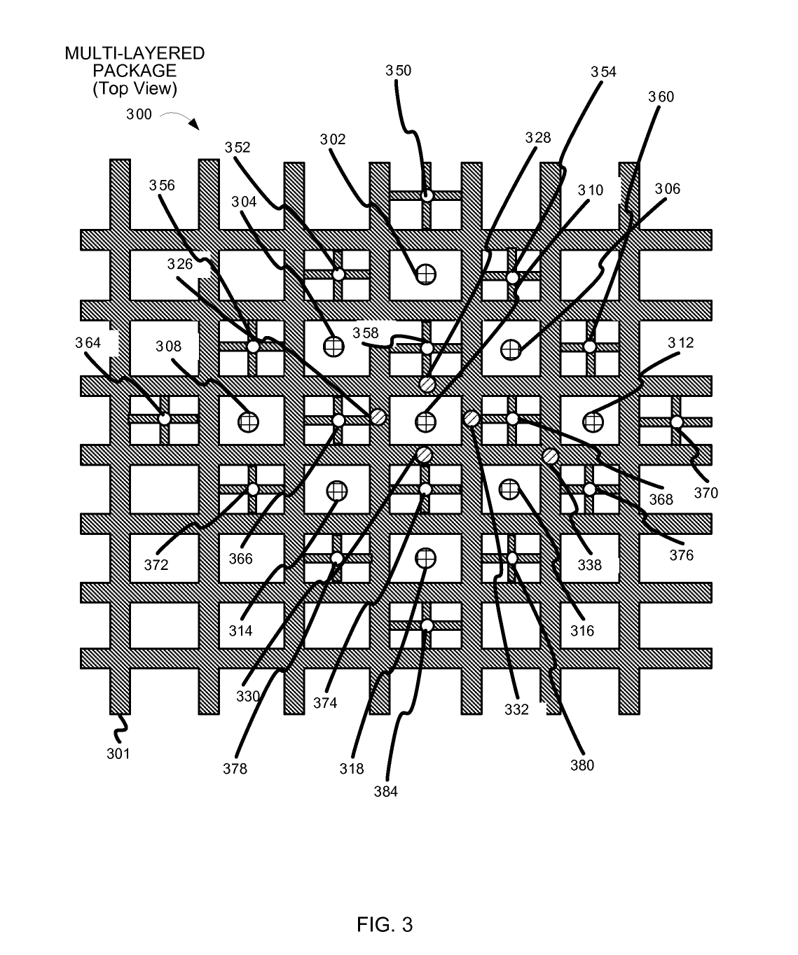

FIG. 3 depicts a top view of a more detailed diagram of a multi-layered package having through-mesh-plane vias, according to some other embodiments. FIG. 3 depicts a top view of a multi-layered package 300 that includes a mesh plane 301. Similar to the multi-layered package 200 of FIG. 2, the multi-layered package 300 includes a number of through-mesh-plane vias that are within the mesh plane and extend to intersect additional mesh planes. However, locations of the through-mesh-plane vias within the mesh plane are different in comparison to the locations of the through-mesh-plane vias in the multi-layered package 200 of FIG. 2. In particular in FIG. 3, the through-mesh-plane vias in the multi-layered package are not positioned at the intersections of the traces of the mesh plane (as will now be described).

As shown, the mesh plane 301 forms a mesh with a number of horizontal lines and vertical lines that criss-cross. In this example, the mesh plane 301 comprises a ground plane. Alternatively, the mesh plane 301 can be a voltage plane. A number of openings are formed in the mesh plane 301 between the intersections of the horizontal lines and vertical lines. There can be a multiple of these mesh planes formed on top of each other at spaced intervals. Also, there can be signal layers formed between the mesh planes. In this example, there are a number of signal vias formed within the openings of the mesh plane 301. In particular, the multi-layered package 300 includes a signal via 302, a signal via 304, a signal via 306, a signal via 308, a signal via 310, a signal via 312, a signal via 314, a signal via 316, and a signal via 318. With reference to FIG. 1, the signal vias 302-318 can examples of the post breakout vias 114.

The multi-layered package 300 also includes a number of through-mesh-plane vias that are within the mesh plane 301. In this example, the multi-layered package 300 includes four through-mesh-plane vias—a through-mesh-plane via 326, a through-mesh-plane via 328, a through-mesh-plane via 330, and a through-mesh-plane via 332. In this example, the through-mesh-plane vias are not positioned at different intersections of the traces of the mesh plane 301.

The through-mesh-plane via 328 is positioned along a horizontal mesh line between the signal via 302 and the signal via 310. The through-mesh-plane via 326 is positioned along a vertical mesh line between the signal via 308 and the signal via 310. The through-mesh-plane via 330 is positioned along a horizontal mesh line between the signal via 310 and the signal via 318. The through-mesh-plane via 332 is positioned along a vertical mesh line between the signal via 310 and the signal via 312. As further described below, the through-mesh-plane vias 326-332 extend down to intersect with one or more mesh planes.

In this example, the multi-layered package 300 also includes a number of ground vias. In this example, the multi-layered package 300 includes 16 ground vias—a ground via 350, a ground via 352, a ground via 354, a ground via 356, a ground via 358, a ground via 360, a ground via 362, a ground via 364, a ground via 366, a ground via 368, a ground via 370, a ground via 372, a ground via 374, a ground via 376, a ground via 378, a ground via 380, a ground via 382, and a ground via 384. In this example, a ground via is positioned in a cross within a mesh opening of the mesh plane 301. The ground vias may be positioned in mesh openings where signal vias are not positioned. In this example, the ground via 350 is positioned in a mesh opening that is above the mesh opening where the signal via 302 is positioned. The ground via 352 is positioned in a mesh opening that is left of the mesh opening where the signal via 302 is positioned. The ground via 354 is positioned in a mesh opening that is right of the mesh opening where the signal via 302 is positioned.

The ground via 356 is positioned in a mesh opening that is left of the mesh opening where the signal via 304 is positioned. The ground via 358 is positioned in a mesh opening that is left of the mesh opening where the signal via 306 is positioned. The ground via 360 is positioned in a mesh opening that is right of the mesh opening where the signal via 306 is positioned. The ground via 364 is positioned in a mesh opening that is left of the mesh opening where the signal via 308 is positioned. The ground via 366 is positioned in a mesh opening that is left of the mesh opening where the signal via 310 is positioned. The ground via 368 is positioned in a mesh opening that is left of the mesh opening where the signal via 312 is positioned. The ground via 370 is positioned in a mesh opening that is right of the mesh opening where the signal via 312 is positioned.

The ground via 372 is positioned in a mesh opening that is left of the mesh opening where the signal via 314 is positioned. The ground via 374 is positioned in a mesh opening that is left of the mesh opening where the signal via 316 is positioned. The ground via 376 is positioned in a mesh opening that is right of the mesh opening where the signal via 316 is positioned. The ground via 378 is positioned in a mesh opening that is left of the mesh opening where the signal via 318 is positioned. The ground via 380 is positioned in a mesh opening that is right of the mesh opening where the signal via 318 is positioned. The ground via 384 is positioned in a mesh opening that is below the mesh opening where the signal via 318 is positioned.

As further described below, the ground vias 350-384 extend down to intersect with one or more other mesh planes. In some embodiments, the ground vias 350-384 can extend down to intersect the same number of other mesh planes as the through-mesh-plane vias 220-242. Alternatively, the ground vias 350-384 can extend down to intersect a different number of other mesh planes as the through-mesh-plane vias 220-242.

Because the through-mesh-plane vias 326-332 are positioned adjacent to and between the signal vias 202-218 and because the through-mesh-plane vias 326-332 are within the mesh plane and extend down to intersect other mesh planes in the multi-layered package 300, the noise coupling among the signals in the signal vias 302-318 is reduced. Based on 3-D EM (electromagnetic) modeling, the locations of the through-mesh plane vias 326-332 (not at the intersections but at the middle of mesh line in a unit mesh or grid) minimize near-end (FE) noise coupling.

Also, while the multi-layered package 200 in FIG. 2 is described with through-mesh-plane vias at the intersections of the mesh traces and the multi-layered package 300 of FIG. 3 is described with through-mesh-plane vias not at the intersections of the mesh traces, in some embodiments, a multi-layered package can include a combination of through-mesh-plane vias at the intersections of the mesh traces and through-mesh-plane vias not at the intersections of the mesh traces.

Also Table 1 set forth below provides a comparison of noise coupling for models with and without through-mesh-plane vias for both near-end and far-end noise coupling:

TABLE 1

| | Crosstalk | |
|---|---|---|
| | Maximum NE (near | Maximum absolute FE |
| Models | end) noise [mV] | (far end) noise [mV] |
| Model without through- | 41.7 | −148.3 |
| mesh-plane vias | | |
| Model with through | 4.9 | −11.6 |
| mesh-plane vias | | |

As shown by the results in Table 1, the use of through-mesh-plane vias can significantly reduce both NE (near end) and FE (far end) noise coupling.

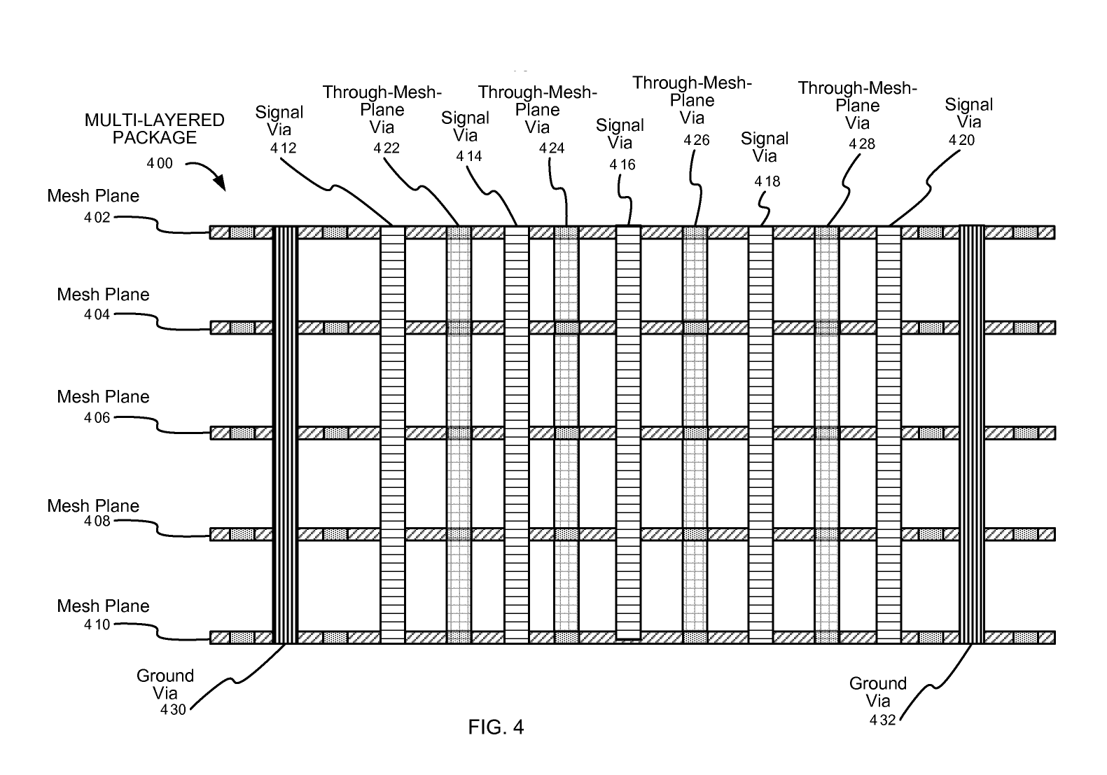

FIG. 4 depicts a cross sectional view of a more detailed diagram of a multi-layered package having through-mesh-plane vias, according to some embodiments. In particular, FIG. 4 depicts a cross sectional view of a multi-layered package 400. The multi-layered package 400 can be representative of either the multi-layered package 200 of FIG. 2 or the multi-layered package 300 of FIG. 3. For example, a mesh plane 402 in the multi-layered package 400 can be representative of the mesh plane 201 of FIG. 2 or the mesh plane 301 of FIG. 3.

The multi-layered package 400 includes a number of mesh planes stacked together. Although not shown, one or more signal layers can be positioned between the number of mesh planes. In this example, the multi-layered package 400 includes five mesh planes—a mesh plane 402, a mesh plane 404, a mesh plane 406, a mesh plane 408, and a mesh plane 410.

The multi-layered package 400 also includes a number of signal vias—a signal via 412, a signal via 414, a signal via 416, a signal via 418, and a signal via 420. The signal vias 412-420 can be positioned in the openings in the mesh planes 402-410 (as described above in references to FIGS. 2-3). The multi-layered package 400 includes a number of through-mesh-plane vias—a through-mesh-plane via 422, a through-mesh-plane via 424, a through-mesh-plane via 426, and a through-mesh-plane via 428. The through-mesh-plane vias 422-428 can be positioned to intersect the mesh planes 402-410 (as described above in references to FIGS. 2-3). The multi-layered package 400 includes a ground via 430 and a ground via 432. The ground vias 430-432 can be positioned in openings of the mesh planes 402-410 yet still electrically coupled to the mesh planes 402-410 through the cross in the openings that are electrically coupled to the mesh planes 402-410. Although not shown, a number of ground vias can overlap the through-mesh-plane vias 422-428.

As shown, the signal via 410 is adjacent to and right of the ground via 430. The through-mesh-plane via 422 is adjacent to and right of the signal via 410. The signal via 414 is adjacent to and right of the through-mesh-plane via 422. The through-mesh-plane via 424 is adjacent to and right of the signal via 414. The signal via 416 is adjacent to and right of the through-mesh-plane via 424. The through-mesh-plane via 426 is adjacent to and right of the signal via 416. The signal via 418 is adjacent to and right of the through-mesh-plane via 426. The through-mesh-plane via 428 is adjacent to and right of the signal via 418. The signal via 420 is adjacent to and right of the through-mesh-plane via 428. The ground via 432 is adjacent to and right of the signal via 420.

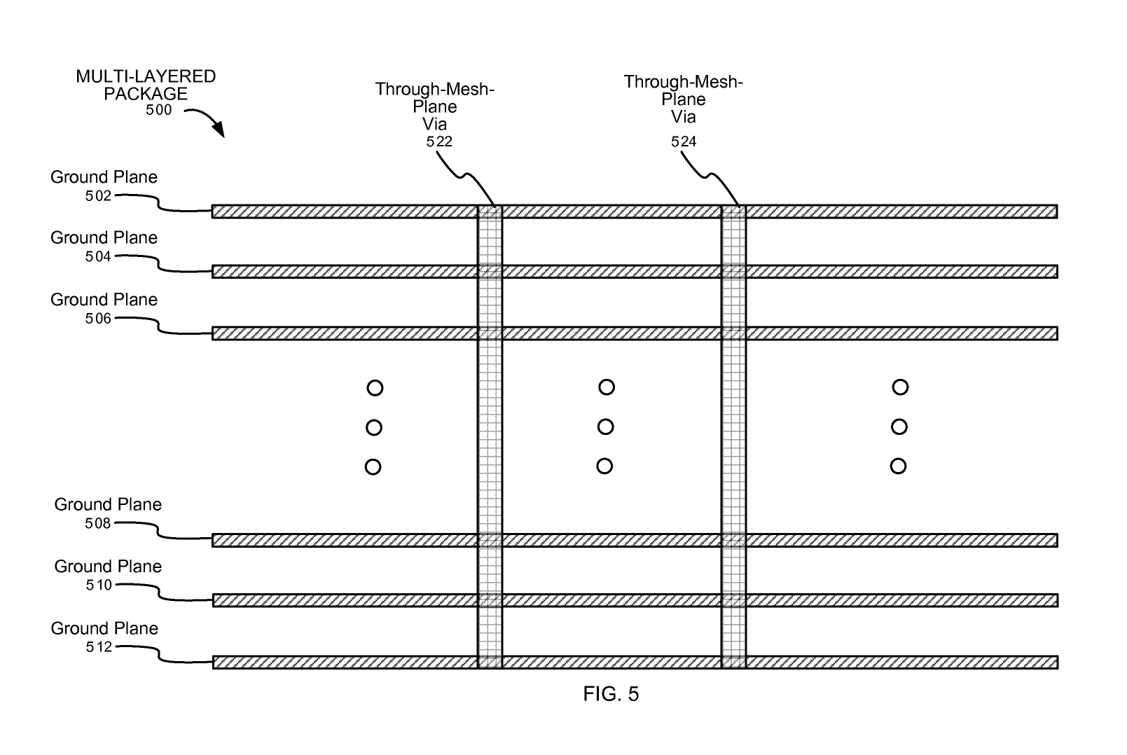

The mesh planes that are intersected by the through-mesh-plane vias can be ground or power planes. FIGS. 5-7 depicts multi-layered packages in which the mesh planes are different combination of ground planes and power planes wherein the mesh planes that are intersected by the through-mesh-plane vias are ground planes. However, in some embodiments, these mesh planes being intersected can alternatively be power planes.

FIG. 5 depicts a cross sectional view of a more detailed diagram of a multi-layered package in which the mesh planes are ground planes, according to some embodiments. In particular, FIG. 5 depicts a cross sectional view of a multi-layered package 500. It should be noted that power planes could be used as the mesh planes rather than ground planes depending on design purpose in FIG. 5. The multi-layered package 500 can be representative of any of the multi-layered package 200 of FIG. 2, the multi-layered package 300 of FIG. 3, or the multi-layered package 400 of FIG. 4. For example, the ground planes 502-512 in the multi-layered package 500 can be representative of the mesh planes 402-410 in the multi-layered package 400 of FIG. 4.

The multi-layered package 500 includes a number of ground planes stacked together. The ground planes are representative of mesh planes. Although not shown, one or more signal layers can be positioned between the number of ground planes. In this example, the multi-layered package 500 includes a ground plane 502, a ground plane 504, a ground plane 506, a ground plane 508, a ground plane 510, and a ground plane 512.

The multi-layered package 500 includes a number of through-mesh-plane vias—a through-mesh-plane via 522 and a through-mesh-plane via 524. The through-mesh-plane vias 522-524 can be positioned to intersect the ground planes 502-510 (as described above in references to FIGS. 2-3).

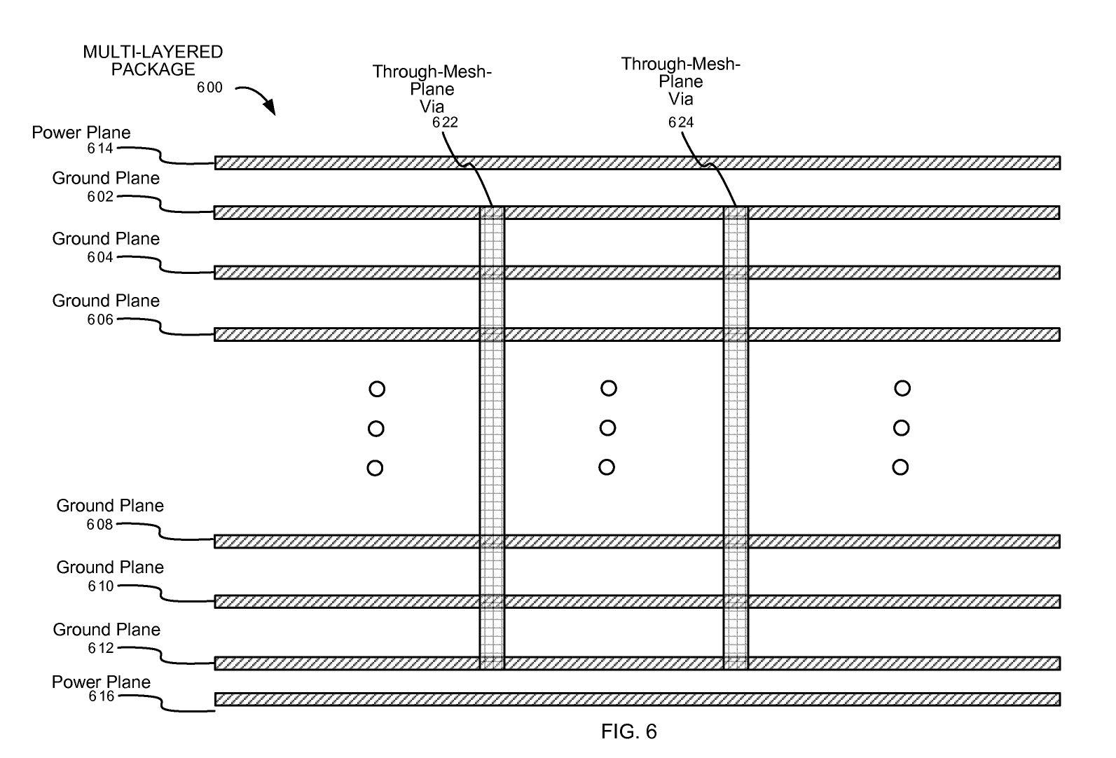

FIG. 6 depicts a cross sectional view of a more detailed diagram of a multi-layered package in which the mesh planes are a combination of ground planes and power planes, according to some embodiments. It should be noted that ground planes and power planes in FIG. 6 can be switched each other depending on design purpose. In particular, FIG. 6 depicts a cross sectional view of a multi-layered package 600. The multi-layered package 600 illustrates a mesh plane configuration in which power planes are included in the mesh plane stack up in which the signal vias exist. In this example, the power planes can be located at the top most layer and bottom most layer to minimize noise coupling between the signal vias. Therefore, the through-mesh-plane vias extend between the top ground plane and the bottom ground plane (but not to the power planes that are positioned above and below the top ground plane and the bottom ground plane).

The multi-layered package 600 can be representative of any of the multi-layered package 200 of FIG. 2, the multi-layered package 300 of FIG. 3, or the multi-layered package 400 of FIG. 4. For example, the ground planes 602-612 in the multi-layered package 600 can be representative of the mesh planes 402-410 in the multi-layered package 400 of FIG. 4. In contrast to the multi-layered package 500 of FIG. 5, the multi-layered package 600 includes mesh planes that are power planes—a power plane 614 and a power plane 616.

The multi-layered package 600 includes a number of ground planes stacked together. The ground planes are representative of mesh planes. Although not shown, one or more signal layers can be positioned between the number of ground planes. In this example, the multi-layered package 600 includes a ground plane 602, a ground plane 604, a ground plane 606, a ground plane 608, a ground plane 610, and a ground plane 612.

The multi-layered package 600 includes a number of through-mesh-plane vias—a through-mesh-plane via 622 and a through-mesh-plane via 624. The through-mesh-plane vias 622-624 can be positioned to intersect the ground planes 602-610 (as described above in references to FIGS. 2-3). Also to ensure that the ground planes 602-614 are not electrically coupled with the power planes 614-616, the power plane 614-616 are not between the ground planes 602-614, and the through-mesh-plane vias 622-624 do not extend to intersect with the power planes 614-616.

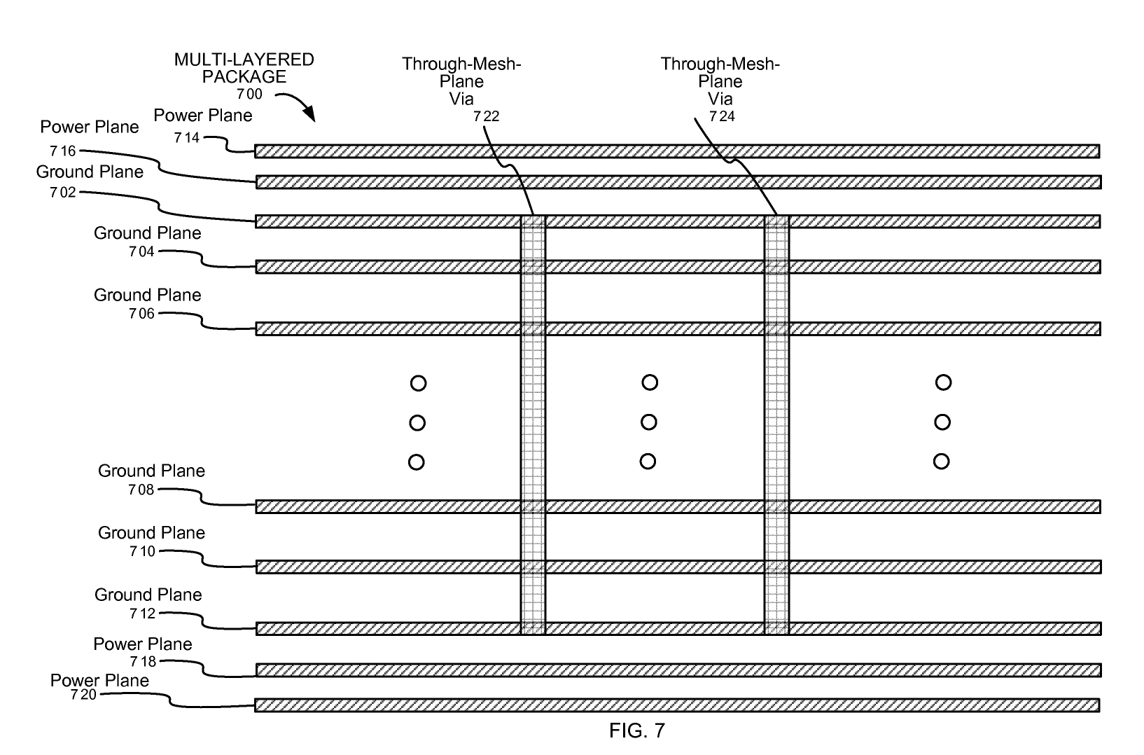

FIG. 7 depicts a cross sectional view of a more detailed diagram of a multi-layered package in which the mesh planes are a combination of ground planes and power planes, according to some other embodiments. It should be noted that ground planes and power planes in FIG. 7 can be switched each other depending on design purpose. In particular, FIG. 7 depicts a cross sectional view of a multi-layered package 700. The multi-layered package 700 illustrates another mesh plane configuration in which power planes are included in the mesh plane stack up in which the signal vias exist. In this example, more than two power planes are included. The power planes can be located at the top most layer and bottom most layer to minimize noise coupling between the signal vias. Therefore, the through-mesh-plane vias extend between the top ground plane and the bottom ground plane (but not to the power planes that are positioned above and below the top ground plane and the bottom ground plane).

The multi-layered package 700 can be representative of any of the multi-layered package 200 of FIG. 2, the multi-layered package 300 of FIG. 3, or the multi-layered package 400 of FIG. 4. For example, the ground planes 702-712 in the multi-layered package 700 can be representative of the mesh planes 402-410 in the multi-layered package 400 of FIG. 4. The multi-layered package 700 includes four mesh planes that are power planes—a power plane 714, a power plane 716, a power plane 718, and a power plane 720.

The multi-layered package 700 includes a number of ground planes stacked together. The ground planes are representative of mesh planes. Although not shown, one or more signal layers can be positioned between the number of ground planes. In this example, the multi-layered package 700 includes a ground plane 702, a ground plane 704, a ground plane 706, a ground plane 708, a ground plane 710, and a ground plane 712.

The multi-layered package 700 includes a number of through-mesh-plane vias—a through-mesh-plane via 722 and a through-mesh-plane via 724. The through-mesh-plane vias 722-724 can be positioned to intersect the ground planes 702-710 (as described above in references to FIGS. 2-3). Also to ensure that the ground planes 702-714 are not electrically coupled to the power planes 714-720, the power plane 714-720 are not between the ground planes 702-714, and the through-mesh-plane vias 722-724 do not extend to intersect with the power planes 714-720.

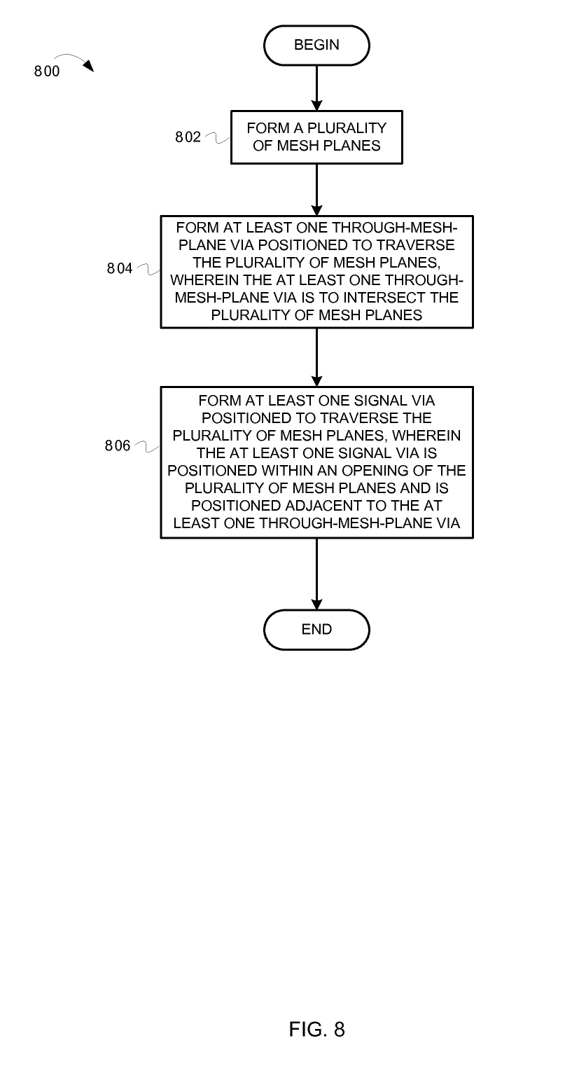

FIG. 8 depicts a flowchart of operations for fabrication of a multi-layered package, according to some embodiments. FIG. 8 is described in reference to the multi-layered package 400 of FIG. 4. However, these operations can be applicable to fabrication of other embodiments of a multi-layered package. Operations of a flowchart 800 begin at block 802.

At block 802, a plurality of mesh planes are formed. With reference to FIG. 4, the mesh planes 402-410 are formed. Operations of the flowchart 800 continue at block 804.

At block 804, at least one through-mesh-plane via positioned to traverse the plurality of mesh planes is formed, wherein the at least one through-mesh-plane via is to intersect the plurality of mesh plane. With reference to FIG. 4, the through-mesh-plane vias 422-428 are formed such that they are positioned to be traverse to the mesh planes 402-410. Also in this example, the through-mesh-plane vias 422-428 are formed to intersect the mesh planes 402-410. Operations of the flowchart 800 continue at block 806.

At block 806, at least one signal via positioned to traverse the plurality of mesh planes is formed, wherein the at least one signal via is positioned within an opening of the plurality of mesh planes and is positioned adjacent to the at least one through-mesh-plane via. With reference to FIG. 4, the signal vias 412-420 are formed such that they are positioned to be traverse to the mesh planes 402-410 and are positioned. Also, the signal vias 412-420 are formed to be positioned with openings of the mesh planes 402-410 and adjacent to the through-mesh-plane vias 422-428. Operations of the flowchart 800 are complete.

While the embodiments are described with reference to various implementations and exploitations, it will be understood that these embodiments are illustrative and that the scope of the inventive subject matter is not limited to them. In general, techniques for the incorporation of through-mesh-plane vias in multilayered packages for reduction of noise coupling between signals as described herein may be implemented with facilities consistent with any hardware system or hardware systems. Many variations, modifications, additions, and improvements are possible.

Plural instances may be provided for components, operations or structures described herein as a single instance. Finally, boundaries between various components, operations and data stores are somewhat arbitrary, and particular operations are illustrated in the context of specific illustrative configurations. Other allocations of functionality are envisioned and may fall within the scope of the inventive subject matter. In general, structures and functionality presented as separate components in the exemplary configurations may be implemented as a combined structure or component. Similarly, structures and functionality presented as a single component may be implemented as separate components. These and other variations, modifications, additions, and improvements may fall within the scope of the inventive subject matter.

What is claimed is:

1. A multi-layered package comprising:
a plurality of mesh planes;
at least one through-mesh-plane via positioned to traverse the plurality of mesh planes, wherein the at least one through-mesh-plane via is to intersect the plurality of mesh planes; and
at least one signal via positioned to traverse the plurality of mesh planes, wherein the at least one signal via is positioned within an opening of the plurality of mesh planes and is positioned adjacent to the at least one through through-mesh-plane via.

2. The multi-layered package of claim 1, wherein each of at least a portion of the plurality of mesh planes comprise a plurality of mesh lines that criss-cross to create a mesh pattern.

3. The multi-layered package of claim 2, wherein the at least one through-mesh-plane via is positioned at an intersection of two of the plurality of mesh lines.

4. The multi-layered package of claim 2, wherein the at least one through-mesh-plane via is positioned along a first mesh line of the plurality of mesh lines at a location that does not intersect with any of the other mesh lines of the plurality of mesh lines.

5. The multi-layered package of claim 1, wherein the plurality of mesh planes comprise a plurality of ground planes that include a top ground plane and a bottom ground plane.

6. The multi-layered package of claim 5, further comprising:
a top power plane positioned above the top ground plane; and
a bottom power plane positioned below the bottom ground plane,
wherein the at least one through-mesh-plane via does not extend to intersect with the top power plane and the bottom power plane.

7. The multi-layered package of claim 1, wherein the plurality of mesh planes comprise a plurality of power planes.

8. A system comprising:
a printed circuit board;
a multi-layered package positioned on top of the printed circuit board and communicatively coupled to the printed circuit board, the multi-layered package comprising,
a plurality of mesh planes;
at least one through-mesh-plane via positioned to traverse the plurality of mesh planes, wherein the at least one through-mesh-plane via is to intersect the plurality of mesh planes; and
at least one signal via positioned to traverse the plurality of mesh planes, wherein the at least one signal via is positioned within an opening of the plurality of mesh planes and is positioned adjacent to the at least one through-mesh-plane via; and
an integrated circuit device positioned on top of the multi-layered package and communicatively coupled to the at least one signal via.

9. The system of claim 8, wherein each of at least a portion of the plurality of mesh planes comprise a plurality of mesh lines that criss-cross to create a mesh pattern.

10. The system of claim 9, wherein the at least one through-mesh-plane via is positioned at an intersection of two of the plurality of mesh lines.

11. The system of claim 9, wherein the at least one through-mesh-plane via is positioned along a first mesh line of the plurality of mesh lines at a location that does not intersect with any of the other mesh lines of the plurality of mesh lines.

12. The system of claim 8, wherein the plurality of mesh planes comprise a plurality of ground planes that include a top ground plane and a bottom ground plane.

13. The system of claim 12, further comprising:
a top power plane positioned above the top ground plane; and
a bottom power plane positioned below the bottom ground plane,
wherein the at least one through-mesh-plane via does not extend to intersect with the top power plane and the bottom power plane.

14. The system of claim 8, wherein the plurality of mesh planes comprise a plurality of power planes.

15. A method comprising:
fabricating a multi-layered package, the fabricating comprising,
forming a plurality of mesh planes;
forming at least one through-mesh-plane via positioned to traverse the plurality of mesh planes, wherein the at least one through-mesh-plane via is to intersect the plurality of mesh planes; and
forming at least one signal via positioned to traverse the plurality of mesh planes, wherein the at least one signal via is positioned within an opening of the plurality of mesh planes and is positioned adjacent to the at least one through-mesh-plane via.

16. The method of claim 15, wherein each of at least a portion of the plurality of mesh planes comprise a plurality of mesh lines that criss-cross to create a mesh pattern.

17. The method of claim 16, wherein the at least one through-mesh-plane via is positioned at an intersection of two of the plurality of mesh lines.

18. The method of claim 16, wherein the at least one through-mesh-plane via is positioned along a first mesh line of the plurality of mesh lines at a location that does not intersect with any of the other mesh lines of the plurality of mesh lines.

19. The method of claim 15, wherein the plurality of mesh planes comprise a plurality of ground planes that include a top ground plane and a bottom ground plane.

20. The method of claim 19, wherein fabricating the multi-layered package comprises:
forming a top power plane positioned above the top ground plane; and
forming a bottom power plane positioned below the bottom ground plane,
wherein the at least one through-mesh-plane via does not extend to intersect with the top power plane and the bottom power plane.
